(19) United States
(12) Patent Application Publication
(10) Pub. No.: US 2026/0321547 A1
(43) Pub. Date: Oct. 15, 2026

(54) WAFER PROCESSING APPARATUS

(71) Applicant: Hitachi High-Tech Corporation, Minato-ku, Tokyo (JP)

(72) Inventors: Tomohiro SHIRAKI, Tokyo (JP); Yutaka KOUZUMA, Tokyo (JP); Kazuyuki HIROZANE, Tokyo (JP)

(21) Appl. No.: 19/108,574

(22) PCT Filed: Sep. 6, 2023
(86) PCT No.: PCT/JP2023/032520

§ 371 Date: Mar. 4, 2025

(51) Int. Cl. H01J 37/32; H10P 72/76

(52) U.S. Cl. CPC H01J 37/32449; H01J 37/32642; H01J 37/32715; H10P 72/7611

(57) ABSTRACT

A wafer processing apparatus including a cylindrical sample stand disposed in a processing chamber for supporting a wafer, a stepped portion for annularly surrounding a wafer mounting surface of the sample stand, a ring shaped gas dispersing plate which is mounted on a bottom surface of the stepped portion, a susceptor ring which is mounted on an upper surface of the gas dispersing plate, and an inert gas flow passage constituted by a gap the gas dispersing plate and the stepped portion, a gap between an inner circumferential side wall of the gas dispersing plate and an outer circumferential side wall of the stepped portion, and a gap between an inner circumferential side wall of the susceptor ring and the outer circumferential side wall of the stepped portion. A vertically extending recess portion is formed in a plurality of positions of the inner circumferential side wall of the susceptor ring.

### TECHNICAL FIELD

The present invention relates to a wafer processing apparatus for executing wafer processing to a film layer as a processing target on a substrate sample such as a semiconductor wafer mounted on the upper surface of a Sample stand in a processing chamber inside a vacuum vessel by supplying gas to a back surface of an outer circumferential edge portion of the wafer along an inner circumferential surface of a ring-like member placed to surround an outer circumference of the upper surface of the sample stand.

### BACKGROUND ART

Japanese Unexamined Patent Application Publication No. 2017-143186 (Patent Literature 1) discloses the etching process to the layer on the semiconductor wafer at the atomic layer level. Specifically, in the etching process, the following process steps are executed. £ In the process step, the active species (radical) of the processing gas generated using plasma is supplied to the upper surface of the semiconductor wafer as the sample for adhesion so that the product layer is formed on the surface. In the subsequent process step, the wafer is irradiated with electromagnetic wave with wavelength including infrared light from lamps placed in the ring-like arrangement while surrounding the area above the wafer to desorb and volatilize the product layer. The etching process is completed by removing the product layer to be generated to have the thickness substantially equivalent to that of the atomic layer.

In the above-described technique, the step (1) for forming the radical reaction product layer, and the step (2) for removing the reaction layer heated by irradiation of electromagnetic waves including infrared light are executed to the wafer mounted on the sample stand (stage) in the processing chamber inside the vacuum vessel. In the reaction layer forming step (1), the processing gas is supplied to the radical generation space above the processing chamber for activating gas so that the radical is generated. The generated radical particles are supplied to the upper surface of the wafer placed in the processing chamber to form the reaction layer via a gas introduction pipe communicated with the lower processing chamber. In the reaction layer removing step (2) to be executed subsequent to the step (1), infrared light is radiated from the lamp placed above the wafer to remove the reaction layer as a result of vaporization of the product on the upper surface of the wafer. Those steps are repeatedly executed alternately to remove the processing target film on the wafer surface.

Meanwhile, in the respective steps for etching processing, the reaction product is generated, a part of which adheres to or deposits on the wall surface in the processing chamber. If the deposit is released from the inner surface of the processing chamber again, and re-adheres to the wafer surface, the pattern defect occurs. This may cause the risk of deteriorating performance of the semiconductor device to be manufactured from the wafer. Especially the product adhering to the side wall surface of the stage exists adhesively around the wafer. The product that is likely to be carried onto the wafer tends to cause reduction in the processing yield.

The chemical or physical cleaning method is used for solution of the above-described problem. Japanese Unexamined Patent Application Publication No. 2022-152246 (Patent Literature 2) discloses how such method is implemented. The disclosed technique is performed by introducing inert gas from the lower part of the stage, diffusing the gas into the processing chamber by directing the gap between the susceptor ring mounted on the dispersing plate and the stage side wall surface upward for allowing flow of the gas, preventing the reaction product from turning to the stage side wall surface and the back surface by the gas flow, and removing the stagnant foreign substance by the heated gas.

### CITATION LIST

### Patent Literature

Patent Literature 1: Japanese Unexamined Patent Application Publication No. 2017-143186

Patent Literature 2: Japanese Unexamined Patent Application Publication No. 2022-152246

### SUMMARY OF INVENTION

### Technical Problem

The conventional art suppresses occurrence of foreign substances owing to adhesion of particles generated in plasma and products generated in the wafer processing to a film surface that covers the outer circumferential side wall surface of the wafer mount surface of the stage, or local depletion of the outer circumferential edge of the film for covering the surface on which the wafer is mounted owing to interaction with the particle and the product by supplying upwardly directed inert gas through a circumferentially uniform gap between the susceptor ring/dispersing plate and the stage. Such metal as SUS is used for making the dispersing plate to be processed at high pressure to secure accuracy of machining the flow passage for inert gas. The dispersing plate is positioned so that variation of the gap from the stage in the circumferential direction is within the allowable range, and the position is fixed to the stage using screws and bolts to reduce unevenness of inert gas supply.

Compared to the metal dispersing plate, the dielectric susceptor ring placed above the dispersing plate is placed by an operator who adjusts its position to reduce variation of the gap between the inner circumference of the susceptor ring and the outer circumferential side wall of the stage in the circumferential direction. This may cause artificial errors. The position of the dielectric susceptor ring is not fixed relative to the dispersing plate placed beneath the susceptor ring because of difference in the thermal expansion amount. Variation of the gap from the outer circumferential side wall surface of the stage becomes large in the circumferential direction as a plurality of wafers are processed.

Displacement of the susceptor ring owing to eccentricity increases variation of the flow rate of gas supplied from the gap between the susceptor ring and the stage in the circumferential direction, resulting in obstruction of gas supply. In the case of high pressure processing, the deposit containing atmosphere is likely to stagnate around the stage at the lower part of the processing chamber. Foreign substances are likely to be generated by adhesion of particles to the stage surface owing to the processing gas, and depletion of the adsorption film (especially, an end portion) that has been reacted with plasma. If polyimide is used as a material for forming the dielectric film to be placed on the upper surface of the stage for electrostatically adsorbing the wafer onto the upper surface of the stage, reaction with halogen radical is likely to occur, which is often used as the gas to be supplied for removing (cleaning) the adhered deposit. In the above-described case, an amount of substance adhered to the stage surface, and the depletion degree increase to generate the foreign substance from the stage. The problem still occurs as it is not taken into account by the conventional art.

As described above, eccentricity of the susceptor ring causes nonuniformity of the edge gas flow passage in the circumferential direction. This results in the problem of the locally depleted stage surface material, and deterioration in the wafer in-plane uniformity.

It is an object of the present invention to provide a wafer processing apparatus capable of securing prolonged stable operation of the stage and improving processing efficiency even in the case of eccentricity of the susceptor ring.

### Solution to Problem

The wafer processing apparatus according to an embodiment of the present invention includes a processing chamber disposed in a vacuum vessel, into which processing gas is supplied, a cylindrical sample stand disposed in the processing chamber for supporting a wafer as a processing target, a stepped portion for annularly surrounding a mount surface of the sample stand, on which the wafer is mounted, a ring shaped gas dispersing plate which is mounted on a bottom surface of the steeped portion to surround the mount surface, a susceptor ring which is mounted on an upper surface of the gas dispersing plate to surround the mount surface, and a flow passage through which inert gas flows, which is constituted by a gap between a bottom surface of the gas dispersing plate and the bottom surface of the stepped portion, a gap between an inner circumferential side wall of the gas dispersing plate and an outer circumferential side wall of the stepped portion, and a gap between an inner circumferential side wall of the susceptor ring and the outer circumferential side wall of the stepped portion. A vertically extending recess portion is formed in a plurality of positions of the inner circumferential side wall of the susceptor ring.

### Advantageous Effects of Invention

According to the present invention, a wafer processing apparatus capable of securing prolonged stable operation of the stage and improving processing efficiency, can be provided.

### BRIEF DESCRIPTION OF DRAWINGS

FIG. 1 is a vertical sectional view schematically showing the structure of a wafer processing apparatus according to an embodiment of the present invention.

FIG. 2 is a vertical sectional view schematically showing the structure of a stage gas introduction mechanism used for an embodiment.

FIG. 3 is a transverse sectional view schematically showing the structure of a dispersing plate of a stage gas introduction mechanism according to the embodiment.

FIG. 4 is a view schematically showing a relation between a susceptor ring and slits of the dispersing plate, which constitute a gas flow passage of the stage gas introduction mechanism according to a first embodiment.

FIG. 5 is a view schematically showing a relation between a modified example of the susceptor ring and slits of the dispersing plate, which constitute the gas flow passage of the stage gas introduction mechanism according to the first embodiment.

FIG. 6 is a transverse sectional view showing a sample stand base material constituting a gas flow passage of a stage gas introduction mechanism according to a second embodiment.

FIG. 7 is a transverse sectional view showing a modified example of the sample stand base material constituting the gas flow passage of the stage gas introduction mechanism according to the second embodiment.

### DESCRIPTION OF EMBODIMENTS

Embodiments of the present invention will be described referring to the drawings.

### First Embodiment

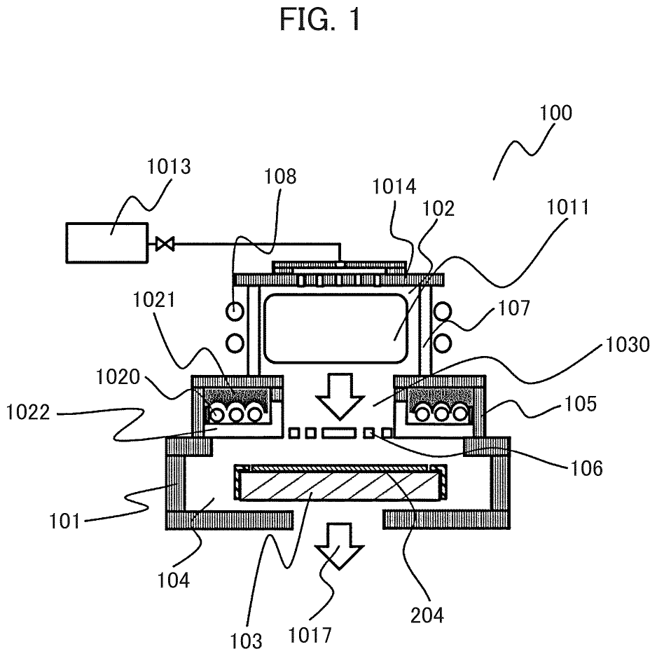

Embodiments of the present invention will be described referring to FIG. 1 to FIG. 5. FIG. 1 is a vertical sectional view schematically showing the structure of a wafer processing apparatus according to an embodiment of the present invention.

A wafer processing apparatus 100 according to an embodiment as shown in FIG. 1 includes a vacuum vessel 101, a discharge unit 102 that constitutes an upper part of the vacuum vessel 101 for generating plasma inside, and a processing chamber 104 that constitutes a lower part of the vacuum vessel, and includes a sample stand 103 on which a semiconductor wafer (hereinafter referred to as a wafer) is mounted. In other words, the sample stand 103 is a stage where the semiconductor wafer to be processed is mounted on an upper mount surface, and placed in the processing chamber 104 inside the vacuum vessel 101. The wafer processing apparatus 100 includes an IR lamp unit 105 for heating the wafer on the sample stand 103, and a processing chamber interior passage 1030 which connects the discharge unit 102 and the processing chamber 104, and is provided with a dielectric dispersing plate 106 having through holes that allow passage of radical particles generated in plasma.

The processing chamber 104 and the discharge unit 102 of the wafer processing apparatus 100 according to the embodiment constitute a cylindrical space, both of which are disposed coaxially or substantially coaxially. The processing chamber 104 and the discharge unit 102 disposed thereabove are connected by the cylindrical processing chamber interior passage 1030 disposed coaxially or substantially coaxially with the processing chamber 104 and the discharge unit 102. The processing chamber and the discharge unit are separated by the circular dispersing plate 106 placed inside the processing chamber interior passage 1030. The discharge unit 102 and the processing chamber 104 are communicated with each other via a plurality of through holes that are concentrically formed in the dispersing plate 106. The gas supplied into the discharge unit 102 is excited to be described later. The gas then flows downwardly toward the processing chamber 104 through the processing chamber interior passage 1030, and is supplied into the processing chamber 104 via the through holes formed in the dispersing plate 106.

The discharge unit 102 is configured to accommodate inflow of the processing gas 1013, and form plasma 1011 to allow optical observation of the plasma state. A processing gas supply passage including the discharge unit 102 is placed above the sample stand 103 so that the processing gas 1013 for processing the wafer is supplied into the processing chamber 104.

The discharge unit 102 includes a cylindrical quartz chamber (dielectric chamber) 107 constituting the upper part of the vacuum vessel 101 to have its inner space communicated with the processing chamber 104 for decompression, and an ICP coil 108 placed outside an outer circumferential side wall surface of the quartz chamber 107, which is wound around the wall surface a plurality of times with a gap. A high frequency power source for forming plasma is connected to the ICP coil 108 via a matching unit. High-frequency power supplied from the high frequency power source forms the plasma 1011 in the quartz chamber 107 by an ICP (Inductively Coupled Plasma) discharge method. The frequency of high frequency power may be in the frequency band of several tens of MHz, for example, 13.56 MHz.

A top plate 1014 is placed over the discharge unit 102. The dispersing plate 106 and a shower plate are placed below the discharge unit 102. The processing gas 1013 is introduced into the vacuum vessel 101 via the dispersing plate 106 and the shower plate. As described above, the introduced processing gas 1013 has its supply flow rate adjusted by a mass flow controller provided for each gas type. As the processing gas 1013, flammable gas, combustion-supporting gas, mixture of those gases, or any of those mixture gases, which is diluted with inert gas may be used. The top plate 1014 is mounted on the quartz chamber 107, and attached to the discharge unit 102 by interposing a sealing member such as an O-ring between the back surface of the outer circumferential edge portion of the top plate and the upper surface of the top end of the quartz chamber 107. A section between the inside of the discharge unit 102 and the outside of the vacuum vessel 101 is sealed air-tightly.

An exhaust hole is formed in the lower part of the processing chamber 104 for decompressing the inside of the vacuum vessel 101. The vacuum vessel 101 is connected to a vacuum pump from the hole via an exhaust pipe. A pressure regulating valve is disposed on a path of the hole and the vacuum pump. The flow rate or flow velocity of exhaust gas 1017 is regulated by increasing or decreasing a flow passage cross section area of the path or the hole.

The sample stand 103 on which the wafer 204 is mounted is placed in the processing chamber 104 at the position coaxially or substantially coaxially with the discharge unit 102 and the processing chamber 104.

The IR lamp unit 105 for heating the wafer 204 is placed above the processing chamber 104, and above an outer circumferential region of the sample stand 103. The IR lamp unit 105 is placed to surround an outer circumference of the processing chamber interior passage 1030. A flow passage through which the radical flows is formed at the center of the IR lamp unit 105. The flow passage is provided with the dielectric dispersing plate 106 having a plurality of concentrically arranged through holes (passages), which shields ions and electrons generated by the plasma, and allows passage of neutral particles or radical particles of the gas. The IR lamp unit 105 is mainly composed of an IR I lamp 1020, a reflecting plate 1021 for reflecting IR light, and a light transmission window 1022 for transmitting the IR light. The IR lamp 1020 for heating the wafer is placed in the atmosphere. The light transmission window 1022 extending from the lower surface of the IR lamp unit 105 to the outer circumferential side wall surface of the processing chamber interior passage 1030 is provided to separate the pressure-reduced atmosphere in the processing chamber 104 from the atmosphere.

A circle type (circular) lamp is used for the IR lamp 1020. The IR lamps 1020 which irradiate the wafer 204 with electromagnetic waves to heat the wafer 204 are placed around the processing gas supply passage in a ring arrangement above the sample stand 103. The IR lamp 1020 emits the light mainly in the range from the visible light to the one in the infrared light region (hereinafter referred to as IR light). The IR lamp 1020 is connected to a lamp power source for power supply. In the embodiment, the near-infrared region from 500 nm to 3000 nm is used for wafer temperature control, and the far infrared region from 3000 nm or greater is used for absorbing IR by cleaning gas. The structure allows the IR lamp 1020 for wafer heating to heat the dispersing plate 106 as well as the wafer 204. The wafer heating light also heats the ion-shielding slit plate. This reduces the deposition amount of radicals of the deposit film to the slit plate, suppressing occurrence of the foreign substance particles owing to generation of the deposit film.

Although not shown, the IR lamps 1020 (three in the drawing) are concentrically arranged on the respective circles each having different radius so that each magnitude of electric power supplied to the respective arcuate parts can be adjusted independently. This makes it possible to adjust a radial distribution of heating amount with respect to the wafer 204.

The wafer processing apparatus 100 according to the embodiment processes the wafer 204 by executing process steps as follows. The process includes a step (1) for forming a reaction product layer on the surface of the wafer 204 by radicals, and a step (2) for removing the reaction product layer by radiating electromagnetic waves including infrared light to heat the surface of the wafer 204.

In the step (1) for generating the reaction product layer, the processing gas 1013 supplied into the discharge unit 102 is activated to generate the plasma 1011. The generated plasma 1011 has ions and electrons shielded by the dispersing plate 106, and only radical particles or neutral particles communicated with the lower processing chamber 104. The plasma is then supplied to the upper surface of the wafer 204 provided in the lower processing chamber 104. As a result, the reaction product layer is formed. In other words, the radical particles or the neutral particles of the processing gas 1013 are introduced onto the wafer 204 mounted on the mount surface of the sample stand 103 to form the reaction product layer on the surface of the processing target film layer preliminarily formed on the upper surface of the wafer 204. The step (2) for removing the reaction product layer is executed subsequent to execution of the step (1). In the step, the infrared light (electromagnetic wave) is radiated from the IR lamp unit 105 disposed above the wafer 204 to vaporize the product on the upper surface of the wafer 204 so that the reaction product layer is removed. Those steps are alternately executed with repetition to remove the processing target film on the surface of the wafer 204.

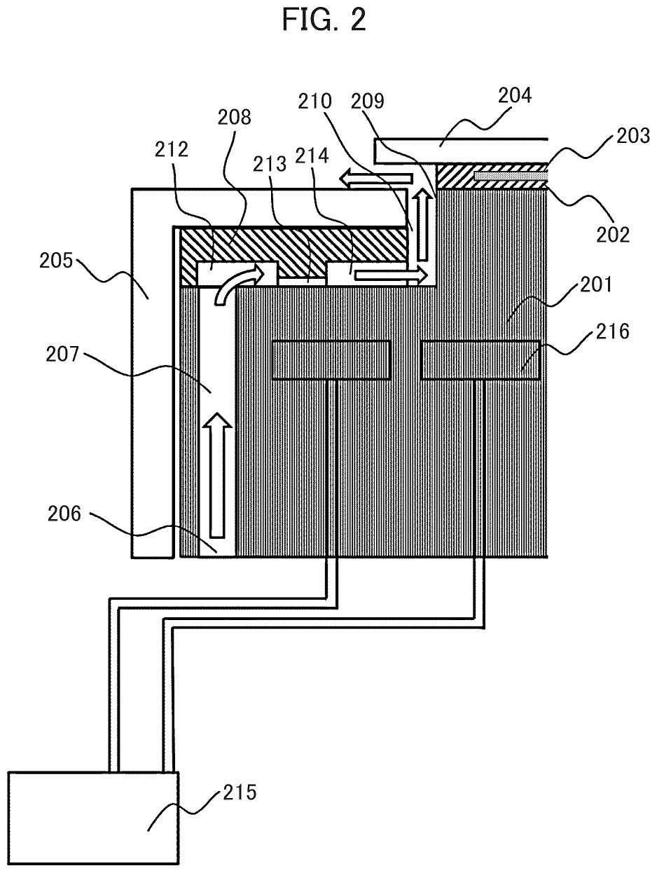

FIG. 2 is a vertical sectional view schematically showing the structure of a stage s gas introduction mechanism for an embodiment as shown in FIG. 1. The Sample stand 103 as shown in the drawing is structured to be column-like shaped and coaxial with the processing chamber 104, which includes a sample stand base material 201 as an inner part, and a sample adsorption film 202 as an upper surface. The sample stand base material 201 has a ring shaped stepped portion, which surrounds an outer circumference of the surface of the sample adsorption film 202. A gas dispersing plate 208 is mounted on a bottom surface of the ring shaped stepped portion, and a susceptor ring 205 is mounted on the upper surface of the gas dispersing plate 208.

A refrigerant flow passage 216 for cooling the sample stand 103 is formed inside the sample stand base material 201 so that the refrigerant is circulatively supplied by a chiller 215. A plate-like electrode plate (electrode for electrostatic adsorption) 203 is embedded in the stage to fix the wafer 204 by electrostatic adsorption, and connected to a DC power source (power source for electrostatic adsorption). In order to efficiently cool the wafer 204, He gas can be supplied between the back surface of the wafer 204 and the sample stand 103. That is, the wafer 204 may be subjected to both functions of fixing adsorption and cooling.

A resin sheet made of polyimide or the like is applied as the sample adsorption film 202 to prevent the back surface of the wafer from being damaged even in the case where the heating/cooling cycle is executed while having the wafer 204 kept adsorbed. In order to fix the wafer 204 by electrostatic adsorption, the plate-like electrode plate 203 is embedded in the sample adsorption film 202. The electrode plate 203 is connected to the DC power source. The sample adsorption film 202 has a groove serving as the path for supplying He gas between the wafer 204 and the sample adsorption film 202. This makes it possible to bring the sample stand 103 under the temperature control by the refrigerant path and the wafer 204 into thermal contact with each other via He gas. The wafer 204 heated by the IR lamp unit 105 is efficiently cooled.

The quartz susceptor ring 205 is provided around the outer circumference of the sample stand 103 so as to be protected from corrosion by etching gas. The cylindrical susceptor ring 205 which is coaxial with the sample stand is designed to have its internal diameter set in accordance with each side wall diameter of the sample stand base material 201 and the sample adsorption film 202. The susceptor ring 205 covers the sample stand 103 except the part on which the wafer 204 is mounted. The susceptor ring 205 is made of a translucent material (quartz, for example) . In other words, the dielectric susceptor ring 205 is disposed on the sample stand 103 while surrounding its mount surface.

The gas dispersing plate 208 is positioned on the upper surface of the ring shaped stepped portion that surrounds the outer circumference of the surface of the sample adsorption film 202 on the sample stand base material 201. The susceptor ring 205 is mounted on the upper surface. The susceptor ring 205 has a cylindrical shape, which is coaxial with the sample stand. The susceptor ring 205 is designed to have its internal diameter set in accordance with the respective side wall diameters of a convex-shaped stage outer circumferential side wall 209, and the sample adsorption film 202, and covers the area from the upper surface of the gas dispersing plate 208 to the outer circumferential side wall surface of the sample stand base material 201. The upper surface of the susceptor ring 205 is designed to be lower than the mount surface (upper surface of the sample adsorption film 202) of the sample stand 103 so that the lower surface of the wafer 204 does not come in contact with the upper surface of the susceptor ring 205. The susceptor ring 205 is made of a translucent material (quartz, for example) . In other words, the dielectric susceptor ring 205 is disposed on the sample stand 103 while surrounding its mount surface.

A stage gas introduction mechanism 206 is provided below the susceptor ring 205 for removing the foreign substance deposited on the side surface of the sample stand 103, and suppressing intrusion of the foreign substance. The stage gas introduction mechanism 206 includes a stage inner pipe 207 and the gas dispersing plate 208. Nonvolatile gas such as Ar (argon), or molecular gas including C—H bond, O—H bond, N—H bond, C═O bond, C═C bond, or C—O bond (referred to as IR absorption gas herein) is introduced as the gas to be supplied through the stage inner pipe 207. The Ar gas is used for the purpose of suppressing intrusion of the reaction product to the side surface of the stage during processing. The IR absorption gas efficiently absorbs energy by resonance of the expansion vibration and bending vibration of molecules with the IR light wavelength. Accordingly, the IR absorption gas can be used to remove the foreign substance by heating.

The IR light radiated from the IR lamp unit 105 has the wavelength in the wavelength band to be absorbed by the gas. In the case where the gas is carbon dioxide, it is preferable that the IR light is in the far-infrared region. Specifically, in the case of the C—H bond in the gas, preferably, the wavelength of the IR light is in the range from 10.1 to 14.9 μm, or from 3.2 to 3.7 μm. In the case of the O-H bond, preferably, the wavelength is in the range from 2.7 to 3.1 μm. In the case of the N—H bond, preferably, the wavelength is 2.9 μm. In the case of the C═O bond in the gas, preferably, the wavelength of the IR light is in the range from 5.5 to 6.5 μm. In the case of the C═C bond, preferably, the wavelength is in the range from 6.1 to 6.3 μm. In the case of the C—O bond, preferably, the wavelength is in the range from 7.7 to 9.6 μm. The IR lamp for radiating the IR light with the above-described wavelength may further be provided within the IR lamp unit 105. Namely, the IR lamp 1020 as shown in FIG. 1 is allowed to serve as a wafer temperature regulating lamp for radiating the IR light in the near-infrared region (wavelength from 0.4 to 3 μm). An IR lamp for radiating the IR light with the above-described wavelength (4 μm or greater) may be added to be arranged outside the IR lamp 1020 in a triple array.

The stage inner pipes 207 are provided at respective eight positions inside the sample stand base material 201 at equal intervals in the circumferential direction. Those pipes are placed just below a ring shaped downstream gas sump 212 formed in the back surface of the gas dispersing plate 208. The stage gas introduction mechanism 206 suppresses adhesion of particles to the stage surface owing to the processing gas, and depletion of the adsorption film (especially, an end portion) by reaction with plasma by executing process steps of circumferentially diffusing the gas supplied from the stage inner pipes 207 at respective eight positions of the mechanism by means of the ring shaped downstream gas sump 212 in the circumferential direction of the sample stand 103, diffusing the gas by means of a ring shaped upstream gas sump 214 at the latter stage again via slits (introduction ports) 213 at respective 16 positions provided at equal angular intervals of 22.5°, and flowing the gas into the processing chamber 104 from around the back surface of the wafer 204 through a minute gap 210 (up to 0.2 mm) between an inner circumferential wall of the susceptor ring 205 mounted on the upper surface of the gas dispersing plate 208 and the stage outer circumferential side wall 209.

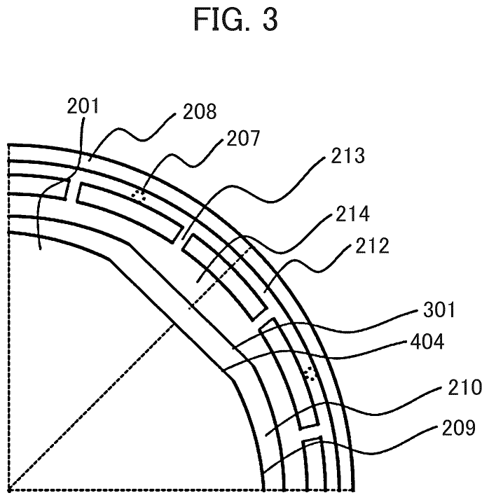

FIG. 3 is a transverse sectional view schematically showing a relation between structure of the gas dispersing plate 208 of the stage gas introduction mechanism 206 according to the embodiment as shown in FIG. 2, and a D cut 404 formed in the sample stand base material 201. This drawing shows structure of a quarter circular sector (a range of the circle cut from the ring at the central angle of 90°) of the ring shaped gas dispersing plate 208 as shown in FIG. 2.

The gas supplied from the stage inner pipes 207 of the stage gas introduction mechanism 206 at respective eight positions is diffused in the circumferential direction of the sample stand 103 by means of the downstream gas sump 212 as the ring shaped space. The gas flows through the slits (introduction ports) 213 at 16 positions at equal angular intervals of 22.5°, and is diffused again by means of the upstream gas sump 214 as the ring shaped space at the latter stage. The stage gas introduction mechanism 206 constitutes a gas flow passage (path) so that the nonvolatile gas or the IR absorption gas is blown from the outer circumferential side of the Sample stand 103 to the side surface of a protruding portion at the center of the sample stand 103.

The gas dispersing plate 208 to be processed at high pressure is made of metal such as SUS as the inert gas flow passage is required to exhibit machining accuracy. Aiming at reducing uneven supply of inert gas, variation of the minute gap 210 from the stage outer circumferential side wall 209 in the circumferential direction is brought into the allowable range by managing the minute gap 210 between the stage outer circumferential side wall 209 of the sample stand base material 201 and the gas dispersing plate 208 in the following manner. That is, the plate is positioned using a D cut 301 of the gas dispersing plate 208 and the D cut 404 of the sample stand base material 201, each having the same shape, and the position is fixed to the sample stand base material 201 using screws and bolts.

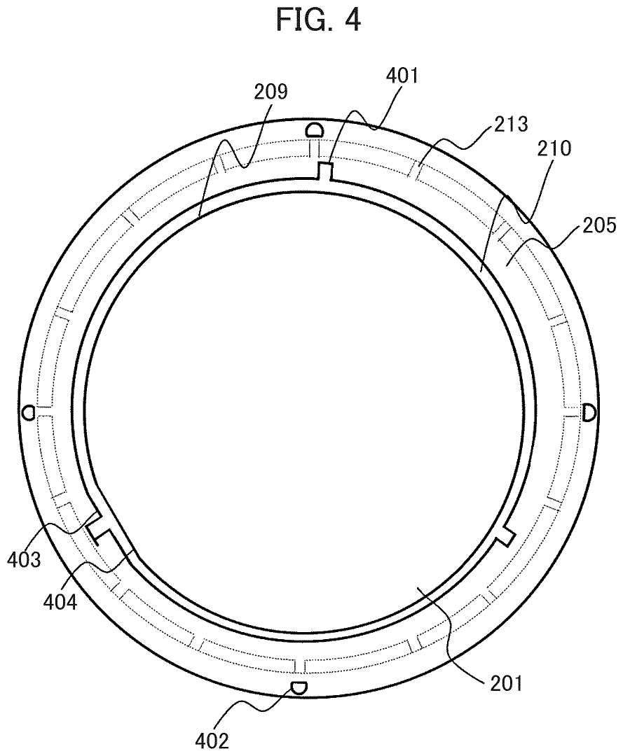

FIG. 4 schematically shows a relation between recess portions 401 of the susceptor ring 205, and the slits (introduction ports) 213 of the gas dispersing plate 208, which constitute the gas flow passage of the stage gas introduction mechanism 206 according to the embodiment as shown in FIG. 2.

The susceptor ring 205 is mounted on the upper surface of the gas dispersing plate 208 fixed to the stage constituting the flow passage of the stage gas introduction mechanism 206 by the bolt. The susceptor ring 205 has a D cut 403, and the sample stand base material 201 has the D cut 404. Those D cuts are formed for positioning, each having the same shape. The position of the D cut 403 formed in the inner circumferential wall of the susceptor ring 205 is aligned to the position of the D cut 404 formed around the wafer mount surface of the sample stand base material 201 for positioning in the circumferential direction so that the susceptor ring 205 is mounted. After mounting the susceptor ring 205, the operator performs centering using the feeler gauge to secure the minute gap 210 between the susceptor ring 205 and the sample stand base material 201 while keeping uniformity in the circumferential direction.

Each of convex-shaped D-type protruding portions 402 for preventing displacement of the wafer has a D cut at the inner circumferential side. They are formed at respective four positions on the upper surface of the susceptor ring 205 for the purpose of supporting the wafer circumferential edge portion when the wafer 204 gets out of position. The recess portions 401 are formed at respective three or more positions in the inner circumferential edge portion of the susceptor ring 205 at equal intervals. The recess portions 401 are placed just above the intermediate positions between slits (introduction ports) 213 of the stage gas introduction mechanism 206, which are formed in the bottom surface of the gas dispersing plate 208 at 16 positions at equal angular intervals of 22.5°.

The metal gas dispersing plate 208 has its position fixed to the sample stand base material 201 using screws and bolts. Meanwhile, the dielectric susceptor ring 205 to be disposed above the metal gas dispersing plate 208 is not fixed to the gas dispersing plate 208, but only placed by the operator who adjusts the position to reduce variation of the minute gap 210 between the inner circumferential wall of the susceptor ring and the stage outer circumferential side wall 209 in the circumferential direction. This may cause an artificial error. This may Cause artificial errors.

Furthermore, during the heating process, input heat causes each temperature of the susceptor ring 205 and the gas dispersing plate 208 for constituting the stage gas introduction mechanism 206 to reach approximately 200° C. It is assumed that the quartz susceptor ring 205 linearly expands by 0.01 mm toward the outer diameter direction, and the SUS gas dispersing plate 208 linearly expands by 0.5 mm toward the outer diameter direction. As a plurality of wafers are processed, eccentricity occurs in the susceptor ring 205 owing to difference in the thermal expansion amount between the susceptor ring and the gas dispersing plate 208. The minute gap 210 becomes nonuniform in the circumferential direction, resulting in unevenness in the flow rate of the stage gas in the circumferential direction. Even if the susceptor ring 205 Causes eccentricity in the rectangular coordinate system in the X and Y directions, leading to the local contact with the stage outer circumferential side wall 209, the recess portions 401 formed in the inner circumferential edge portion of the susceptor ring 205 at respective three or more positions at equal intervals prevent stagnation of the local gas flow of inert gas flowing from the minute gap 210 to the processing chamber 104. This makes it possible to suppress the stage gas from becoming nonuniform in the circumferential direction.

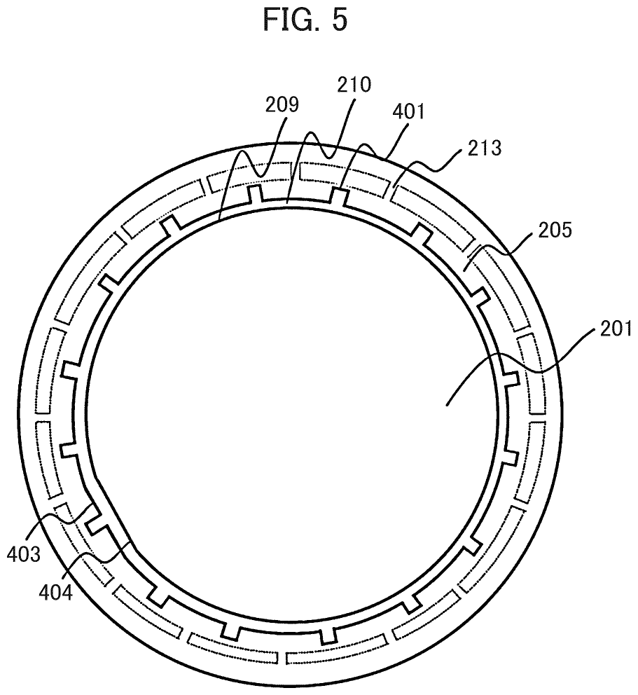

FIG. 5 schematically shows a relation between a modified example of the recess portions 401 of the susceptor ring 205 as shown in FIG. 4 and the slits (introduction ports) 213 of the gas dispersing plate 208. Referring to FIG. 4, the recess portions 401 are formed in the inner circumferential edge portion of the susceptor ring 205 at three intermediate positions between the slits (introduction ports) 213 of the stage gas introduction mechanism 206, which are formed at 16 positions of the stage gas introduction mechanism 206. Referring to FIG. 5, the recess portions 401 are formed in the inner circumferential edge portion of the susceptor ring 205 at 16 intermediate positions between the slits (introduction ports) 213 of the stage gas introduction mechanism 206, which are formed at 16 positions at equal intervals. The modified example as shown in FIG. 5 provides more notable effects for suppressing nonuniformity of the stage gas in the circumferential direction than the example as shown in FIG. 4.

### Second Embodiment

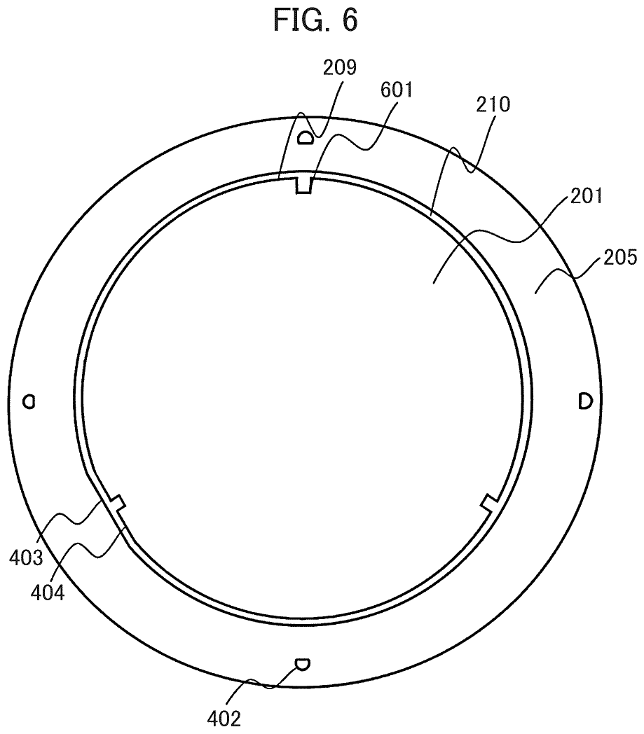

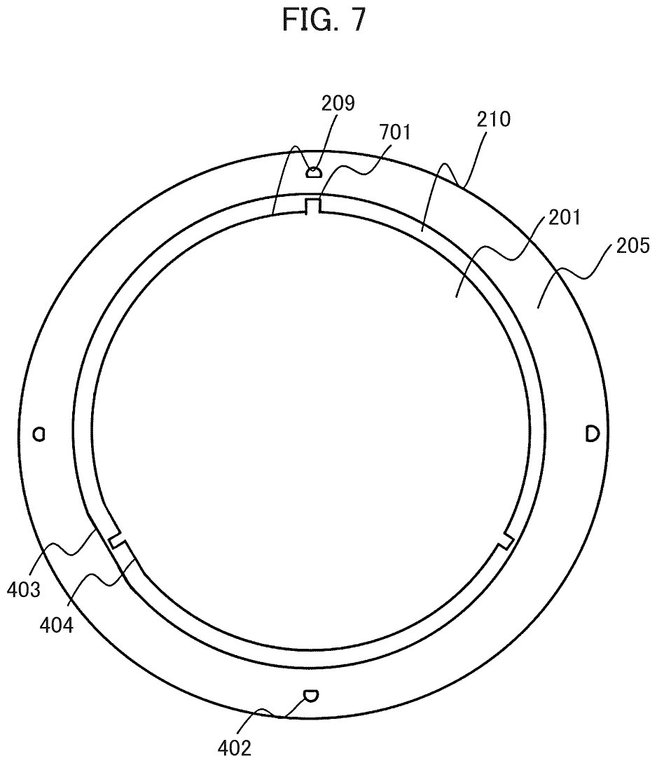

FIGS. 6 and 7 show a transverse sectional view showing a modified example of the sample stand base material 201 constituting the gas flow passage of the stage gas introduction mechanism according to the embodiment as shown in FIG. 2.

In the modified example as shown in FIG. 6, vertically extending recess portions 601 are formed at respective three or more positions in the stage outer circumferential side wall 209 of the sample stand base material 201 constituting the minute gap 210 of the stage gas introduction mechanism 206 at equal intervals in the circumferential direction. £ Aiming at reducing unevenness in the stage gas supply to the upper surface of the sample stand base material 201, positioning is performed using the D cut 301 of the gas dispersing plate 208 and the D cut 404 of the sample stand base material 201, each of which has the same shape so that the position is fixed to the sample stand base material 201 using the screw and the bolt. The minute gap 210 between the stage outer circumferential side wall 209 of the sample stand base material 201 and the gas dispersing plate 208 is managed. The recess portions 601 formed in the stage outer circumferential side wall 209 of the sample stand base material 201 are placed at intermediate positions between the slits (introduction ports) 213 of the gas dispersing plate 208 at 16 positions for stage gas (inert gas) at equal angular intervals of 22.5°. This makes it possible to suppress the flow-rate unevenness in the circumferential direction by preventing local stagnation of the stage gas flow in spite of eccentricity of the susceptor ring 205 in the rectangular coordinate system in X and Y directions. In the second embodiment, the upper surface of the inner circumferential edge portion of the susceptor ring 205 has the D cut 403 for positioning, and the other upper surface of the inner circumferential edge portion has the smooth inner circumferential wall.

As a modified example of FIG. 7 shows, vertically extending protruding portions 701 may be formed at respective three or more positions on the stage outer circumferential side wall 209 of the sample stand base material 201 constituting the minute gap 210 of the stage gas introduction mechanism 206 at equal intervals in the circumferential direction. The protruding portions 701 are placed at positions including intermediate positions between the slits (introduction ports) 213 formed at 16 positions for inert gas, which are formed in the gas dispersing plate 208 fixed to the sample stand base material 201 using the bolt at equally spaced four or more positions at angular intervals of 22.5°. This makes it possible to suppress the flow rate nonuniformity in the circumferential direction by preventing local stagnation of the gas flow in spite of eccentricity of the susceptor ring 205 in the rectangular coordinate system in X and Y directions. In the second embodiment, the upper surface of the inner circumferential edge of the susceptor ring 205 has the D cut 403 for positioning, and smooth inner circumferential wall in the circumferential direction.

The invention made by the present inventors has been described specifically based on embodiments. The present invention, however, is not limited to those embodiments, but may be variously changed without departing from the spirit and scope of the present invention.

### LIST OF REFERENCE SIGNS

100: wafer processing apparatus, 101: vacuum vessel, 102: discharge unit, 103: sample stand, 104: processing chamber, 105: IR lamp unit, 106: dispersing plate, 107: quartz chamber, 108: ICP coil, 201: sample stand base material, 202: sample adsorption film, 203: electrode plate, 204: wafer, 205: susceptor ring, 206: stage gas introduction mechanism, 207: stage inner pipe, 208: gas dispersing plate, 209: stage outer circumferential side wall, 210: minute gap, 212: downstream gas sump, 213: slit (introduction port), 214: upstream gas sump, 215: chiller, 216: refrigerant flow passage, 301: D cut, 401: recess portion, 402: D-type protruding portion for preventing displacement of wafer, 403: D cut, 404: D cut, 601: recess portion, 701: protruding portion, 1011: plasma, 1013: processing gas, 1014: top plate, 1017: exhaust gas, 1020: IR lamp, 1021: reflecting plate, 1022: transmission window, 1030: processing chamber interior passage

1. A wafer processing apparatus comprising:
a processing chamber disposed in a vacuum vessel, into which processing gas is supplied;
a cylindrical sample stand disposed in the processing chamber for supporting a wafer as a processing target;
a stepped portion for annularly surrounding a mount surface of the sample stand, on which the wafer is mounted;
a ring shaped gas dispersing plate which is mounted on a bottom surface of the steeped portion to surround the mount surface;
a susceptor ring which is mounted on an upper surface of the gas dispersing plate to surround the mount surface; and
a flow passage through which inert gas flows, the flow passage being constituted by a gap between a bottom surface of the gas dispersing plate and the bottom surface of the stepped portion, a gap between an inner circumferential side wall of the gas dispersing plate and an outer circumferential side wall of the stepped portion, and a gap between an inner circumferential side wall of the susceptor ring and the outer circumferential side wall of the stepped portion,
wherein a vertically extending recess portion is formed in a plurality of positions of the inner circumferential side wall of the susceptor ring.

2. The wafer processing apparatus according to claim 1,
wherein the recess portion is formed in at least three or more positions along an inner circumference at equal intervals.

3. The wafer processing apparatus according to claim 1,
wherein: the gap between the bottom surface of the gas dispersing plate and the bottom surface of the stepped portion is constituted by a ring shaped downstream gas sump, a ring shaped upstream gas sump, and a plurality of slits for connecting the downstream gas sump and the upstream gas sump; and
each of the recess portions is disposed at an intermediate position between the slits in the circumferential direction.

4. A wafer processing apparatus comprising:
a processing chamber disposed in a vacuum vessel, into which processing gas is supplied;
a cylindrical sample stand disposed in the processing chamber for supporting a wafer as a processing target;
a stepped portion for annularly surrounding a mount surface of the sample stand, on which the wafer is mounted;
a ring shaped gas dispersing plate which is mounted on a bottom surface of the steeped portion to surround the mount surface;
a susceptor ring which is mounted on an upper surface of the gas dispersing plate to surround the mount surface; and
a flow passage through which inert gas flows, the flow passage being constituted by a gap between a bottom surface of the gas dispersing plate and the bottom surface of the stepped portion, a gap between an inner circumferential side wall of the gas dispersing plate and an outer circumferential side wall of the stepped portion, and a gap between an inner circumferential side wall of the susceptor ring and the outer circumferential side wall of the stepped portion,
wherein a vertically extending recess portion is formed in a plurality of positions of the outer circumferential side wall of the stepped portion.

5. The wafer processing apparatus according to claim 4,
wherein the recess portion is formed in at least three or more positions along an outer circumference at equal intervals.

6. The wafer processing apparatus according to claim 4,
wherein: the gap between the bottom surface of the gas dispersing plate and the bottom surface of the stepped portion is constituted by a ring shaped downstream gas sump, a ring shaped upstream gas sump, and a plurality of slits for connecting the downstream gas sump and the upstream gas sump; and
each of the recess portions is disposed at an intermediate position between the slits in the circumferential direction.

7. A wafer processing apparatus comprising:
a processing chamber disposed in a vacuum vessel, into which processing gas is supplied;
a cylindrical sample stand disposed in the processing chamber for supporting a wafer as a processing target;
a stepped portion for annularly surrounding a mount surface of the sample stand, on which the wafer is mounted;
a ring shaped gas dispersing plate which is mounted on a bottom surface of the steeped portion to surround the mount surface;
a susceptor ring which is mounted on an upper surface of the gas dispersing plate to surround the mount surface; and
a flow passage through which inert gas flows, the flow passage being constituted by a gap between a bottom surface of the gas dispersing plate and the bottom surface of the stepped portion, a gap between an inner circumferential side wall of the gas dispersing plate and an outer circumferential side wall of the stepped portion, and a gap between an inner circumferential side wall of the susceptor ring and the outer circumferential side wall of the stepped portion,
wherein a vertically extending protruding portion is formed in a plurality of positions of the t outer circumferential side wall of the stepped portion.

8. The wafer processing apparatus according to claim 7,
wherein the protruding portion is formed in at least three or more positions along an outer circumference at equal intervals.

9. The wafer processing apparatus according to claim 7,
wherein: the gap between the bottom surface of the gas dispersing plate and the bottom surface of the stepped portion is constituted by a ring shaped downstream gas sump, a ring shaped upstream gas sump, and a plurality of slits for connecting the downstream gas sump and the upstream gas sump; and
each of the protruding portions is disposed at an intermediate position between the slits in the circumferential direction.
